(19) United States
(12) Patent Application Publication
(10) Pub. No.: US 2016/0268006 A1
(43) Pub. Date: Sep. 15, 2016

(54) MEMORY SYSTEM AND METHOD OF CONTROLLING MEMORY SYSTEM

(71) Applicant: Kabushiki Kaisha Toshiba, Minato-ku (JP)

(72) Inventor: Hiroaki Tanaka, Hadano (JP)

(73) Assignee: Kabushiki Kaisha Toshiba, Minato-ku (JP)

(21) Appl. No.: 14/824,402

(22) Filed: Aug. 12, 2015

Related U.S. Application Data
(60) Provisional application No. 62/131,017, filed on Mar. 10, 2015.

(51) Int. Cl. G11C 29/38; G11C 29/36; G11C 29/42

(52) U.S. Cl. CPC G11C 29/38; G11C 29/42; G11C 29/36

(57) ABSTRACT

According to one embodiment, a patrol read is performed when a command having a state of being in a process of executing access to a nonvolatile first memory is not present and a host interface transmits read data. The patrol read includes reading data and testing the read data. The read data is data of a certain unit stored in the first memory.

### CROSS-REFERENCE TO RELATED APPLICATIONS

This application is based upon and claims the benefit of priority from U.S. Provisional Application No. 62/131,017, filed on Mar. 10, 2015; the entire contents of which are incorporated herein by reference.

### FIELD

Embodiments described herein relate generally to a memory system including a nonvolatile memory and a method of controlling the same.

### BACKGROUND

In a storage system including a nonvolatile memory such as a flash memory, a maintenance process called patrol read is performed. The patrol read is a process in which data of each predetermined unit stored in the nonvolatile memory is read and tested so as to detect a block having an increased number of errors. In the patrol read, data is read and tested from the entire area of the nonvolatile memory during a predetermined time of one cycle.

The patrol read is executed between processing of commands from the host device such as read and write, as it is intended to be invisible from the host device. For this reason, there has been desired a method for reducing latency times of both processing of a command from the host device and processing of the patrol read and improving the efficiency of both of them.

### BRIEF DESCRIPTION OF THE DRAWINGS

FIG. 1 is a functional block diagram that illustrates an example of the internal configuration of a memory system;

FIG. 2 is a diagram that illustrates an example of the circuit configuration of a memory cell array;

FIG. 3 is a diagram that illustrates a relation between an average erase count and a cycle time;

FIG. 4 is a conceptual diagram that illustrates a patrol read process;

FIG. 5 is a conceptual diagram that illustrates a command queue;

FIG. 6 is a timing chart that illustrates the operating state of each unit at the time of executing a read process;

FIG. 7 is a timing chart that illustrates the operating state of each unit at the time of executing a read process and a patrol read process;

FIG. 8 is a flowchart that illustrates an example of the operation of a control unit; and

FIG. 9 is a diagram that illustrates a relation between the number of had blocks and a cycle time.

### DETAILED DESCRIPTION

According to one embodiment, a memory system includes: a first memory; a second memory; a host interface; and a controller. The first memory is a nonvolatile memory. the second memory is a volatile memory. The host interface is connectable to a host. The controller reads first data from the first memory. The first data is data specified by a first command received from the host through the host interface. The first command is a read command. The controller buffers the read first data into the second memory. The controller transmits the buffered first data to the host through the host interface. The controller perform patrol read when a second command having a state of being in a process of executing access to the first memory is not present and the host interface transmits the first data. The second command is a command received from the host and includes the first command. The patrol read includes reading the second data and testing the read second data. The second data is data of a certain unit stored in the first memory.

Hereinafter, memory systems and methods of controlling a memory system according to embodiments will be described in detail with reference to the accompanying drawings. However, the present invention is not limited to such embodiments.

### First Embodiment

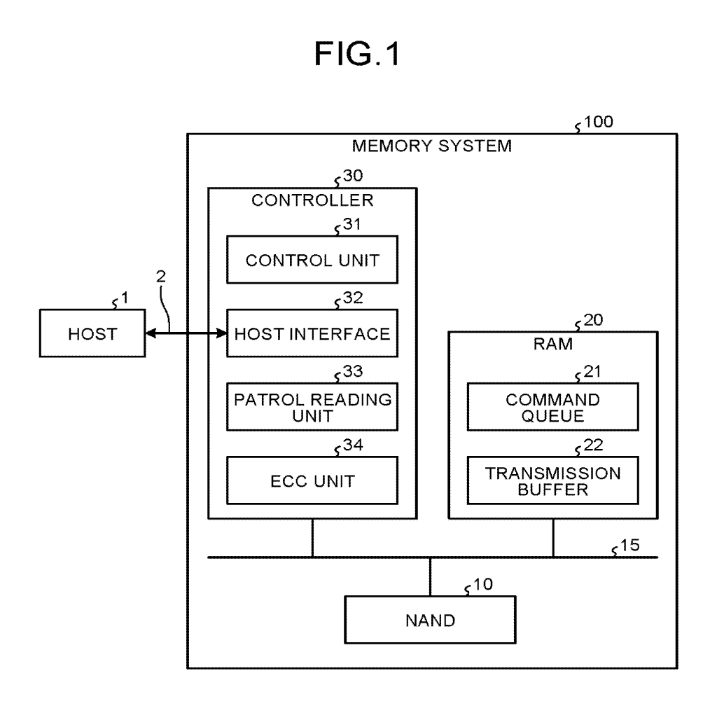

FIG. 1 is a block diagram that illustrates an example of the internal configuration of a solid state drive (SSD) as a memory system according to this embodiment. The memory system 100 is connected to a host device (hereinafter, abbreviated as a host) through a communication line 2 and functions as an external storage device of the host 1. The host 1, for example, may be an information processing apparatus such as a personal computer, a mobile phone, or an imaging apparatus, may be a mobile terminal such as a tablet computer or a smartphone, a gaming device, or an in-vehicle terminal such as a car navigation system.

In this embodiment, while the communication line 2 is a serial advanced technology attachment (SATA) interface, any of other communication lines of PCI express (PCIe), a serial attached SCSI (SAS), and the like may be used. Such a communication line 2 is a serial interface. In the communication line 2, bidirectional communication is performed for information transmission in a low layer such as a physical layer or a data link layer. Regarding host command and user data that is transmitted/received in a transport layer, either one of the host command and the use data can be transmitted at the same time.

The memory system 100 includes: a NAND flash memory (hereinafter, abbreviated as a NAND) 10 as a nonvolatile memory; a RAM 20 being a volatile semiconductor memory capable of higher-speed access than the nonvolatile memory 10; a controller 30; and a bus 15. The nonvolatile memory is not limited to the NAND flash memory but may be a flash memory having a three-dimensional structure, a resistance random access memory (ReRAM), a ferroelectric random access memory (FeRAM), or the like.

The NAND 10 includes one or more memory chips each including a memory cell array. The memory cell array includes a plurality of memory cells arranged in a matrix pattern. The memory cell array includes a plurality of blocks that are units for data erasing. Each block is configured by a plurality of physical sectors.

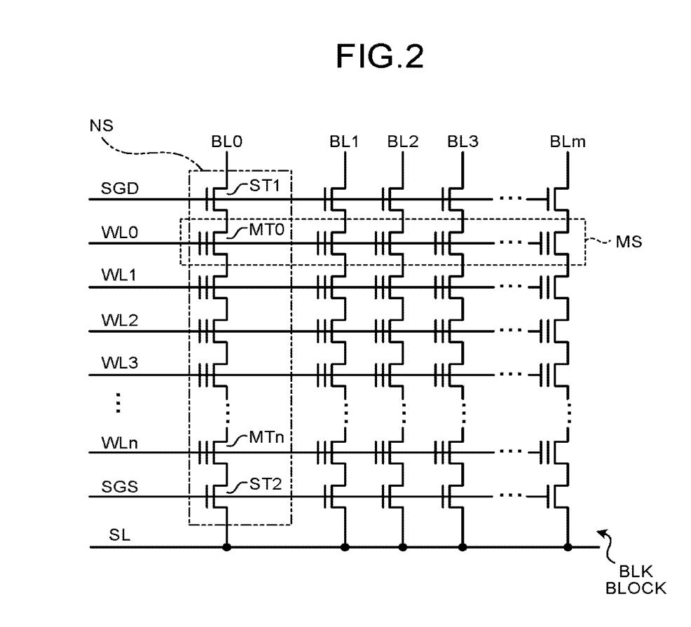

FIG. 2 is a diagram that illustrates an example of the configuration of a block of the memory cell array. FIG. 2 illustrates one of a plurality of blocks that configure the memory cell array. The other blocks of the memory cell array have the same configuration as that illustrated in FIG. 2. As illustrated in FIG. 2, the block ELK of the memory cell array includes (m+1) (here, m is an integer or “0” or more) NAND strings NS. Each NAND string NS shares a diffusion region (a source region or a drain region) between memory cell transistors MT adjacent to each other. Each NAND string NS includes: (n+1) (here, n is an integer of hero or more) memory cell transistors MT0 to MTn connected in series; and selection transistors ST1 and ST2 arranged at both ends of the column of the (n+1) memory cell transistors MT0 to MTn.

Word lines WL0 to WLn are respectively connected to control gate electrodes of the memory cell transistors MT0 to MTn that configure the NAND string NS, and, memory cell transistors MTI (here, i=0 to n) included in each NAND string NS are commonly connected using the same word line WLi (here, i=0 to n). In other words, the control gate electrodes of the memory cell transistors MTi disposed in the same row within the block ELK are connected to the same word line WLi.

Each of the memory cell transistors MT0 to MTn is configured by a field effect transistor having a stacked gate structure on a semiconductor substrate. Here, the stacked gate structure includes: a charge storage layer (floating gate electrode) formed on the semiconductor substrate with a gate insulating film being interposed therebetween; and a control gate electrode formed on the charge storage layer with an inter-gate insulating film being interposed therebetween. A threshold voltage of each of the memory cell transistors MT0 to MTn changes according to the number of electrons storable in the floating gate electrode and thus, can store data according to a difference in the threshold voltage.

Bit lines BL0 to BLm are respectively connected to the drains of (m+1) selection transistors ST1 within one block BLK, and a selection gate line SGD is commonly connected t the gates of the selection transistors. In addition, the source of the selection transistor ST1 is connected to the drain of the memory cell transistor MT0. Similarly, a source line SL is commonly connected the sources of the (m+1) selection transistors ST2 within one block BLK, and a selection gate line SGS is commonly connected to the gates of the selection transistors. addition, the drain of the selection transistor ST2 is connected to the source of the memory cell transistor MTn.

Each memory cell is connected to the word line and connected to the bit line. Each memory cell can be identified by using an address used for identifying a word line and an address used for identifying a bit line. As described above, the data of the plurality of memory cells (the memory cell transistors MT) disposed within the same block ELK is erased altogether. On the other hand, data is written and read in units of physical sectors MS. One physical sector M includes a plurality of memory cells connected to one word line.

In a case where the memory cells are single level cells (SLC), one physical sector MS corresponds to one page. On the other hand, in a case where the memory cells are multiple level cells (MLC), one physical sector MS corresponds to two pages (a lower page and an upper page). In a case where the memory cells are triple level cells (TLC), one physical sector MS corresponds to three pages (a lower page, a middle page, and an upper page).

In a read operation and a program operation, one word line is selected and one physical sector MS is selected according to the physical address. A page switching within this physical sector MS is performed using the physical address.

User data transmitted from the host 1, management information of the memory system 100, and firmware operating a CPU (not illustrated) that configures the controller 30 of the memory system 100 are stored in the NAND 10. The firmware described above may be stored in a ROM not illustrated. The management information described above includes a logical/physical translation table, a block management table, and the like.

Mapping associating a logical address used by the host 1 and a physical address of the RAM 20 or the NAND 10 with each other is registered in the logical/physical translation table. For the logical address, for example, logical block addressing (LPA) is used. The physical address represents a storage position on the NAND 10 in which data is stored.

In the block management table, for example, the following block management information is managed.

(a) Number of times of erasing in units of blocks
(b) Use state of a block (identification information used for identifying an active block or a free block)
(c) Identification information of a bad block (block address)

An active block is a block in which valid data is recorded. A free block is a block that has no valid data being recorded therein and can be reused after erasing data. The valid data is data that is associated with a logical address, and invalid data is data that is not associated with a logical address. A bad block is an unusable block that does riot normally operate due to various factors.

The RAM 20 includes a command queue 21 and a transmission buffer 22. The command queue 21 includes a plurality of entries that manage commands received from the host 1. The command queue 21 stores co ands received from the host 1 in the entries until the process of the memory system 100 is completed. In addition, the command queue 21 records and manages the process status of each command in the memory system 100 in association with each entry. The transmission buffer 22 temporarily buffers data read from the NAND 10 before transmitting the data to the host 1. In addition, the RAM 20 is used also as a reception buffer that temporarily buffers write data received from the host 1 before storing the data in the NAND 10, a buffer in which firmware stored in the NAND 10 is loaded, and a buffer in which the management information stored in the NAND 10 is loaded. The RAM 20, for example, is a dynamic random access memory (DRAM) or a static random access memory (SRAM).

The controller 30 includes: a control unit 31; a host interface 32; a patrol reading unit 33; and an error correction unit (ECC unit) 34. In this embodiment, while an example is described in which the RAM 20 is arranged independently from the controller 30, the RAM 20 may be arranged inside the controller 30. The function of the control unit 31 is realized by one or a plurality of CPUs (processors) executing firmware loaded into the RAM 20 and peripheral circuits thereof. The function of the host interface 32 is realized by hardware and/or a CPU that executes the firmware. The function of the patrol reading unit 33 is realized by hardware and/or a CPU that executes the firmware. In addition, the function of the error correction unit (ECC unit) 34 is realized by hardware and/or a CPU that executes the firmware.

The host interface 32 controls the communication line 2 that connects the host 1 and the memory system 100. The host interface 32 receives commands such as a read command and a write command from the host 1. An address and a size of data and the data are attached to each command. The host interface 32 transmits data buffered in the transmission buffer 22 of the RAM 20 to the host 1.

The patrol reading unit 33 executes patrol read. The patrol read is an operation for checking whether data stored in the NAND 10 is lost due to degradation of a memory cell or the like. In a memory cell transistor, after data is written, the number of electrons stored in a floating gate electrode gradually increases or decreases due to the influence of reading data of the cell or an adjacent cell, writing data into an adjacent cell, and the like or due to the retention of the data for a long time. As a result, information recorded in the memory cell transistor is erroneously read (error bit). Since the characteristics of individual cells and the influences on the cells are different from each other, the time at which an error bit occurs is different for each cell. When the NAND 10 is viewed as a whole, the number of error bits increases according to an elapse of time. From the viewpoint of reading data, while the number of error bits is small at the beginning after data is written, the number of error hits gradually increases according to an elapse of time. While the number of error bits is small, the write data can be restored through a decoding process performed by the ECC unit 34 by using an error correction code (ECC) added in units for reading, for example, in units of pages. However, when the number of error bits increases above a certain level, the write data cannot be restored in the decoding process performed by the ECC unit 34. When the error correction cannot be performed by the ECC unit 34, the memory system 100 loses the write data.

In order to detect a block in which the number of error bits has increased, the patrol reading unit 33 performs a patrol read process in which data of each certain unit stored in the NAND 10 is read, and it is tested whether the read data is normal or abnormal. For example, the patrol reading unit 33 determines abnormality in a case where the number of error bits of the data read in a certain unit exceeds a threshold and determines normality in a case where the number of error bits does not exceed the threshold. The patrol read process is independently performed by the memory system 100 without receiving an instruction from the host 1.

The ECC unit 34 performs an encoding process in which an error correction code (FCC) is added to the write data that is data to be written into the NAND 10. In addition, the ECC unit 34 performs a decoding process in which an error correction is performed for the data read from the NAND 10 by using the error correction code (FCC) The ECC unit 34 has a function for reporting the degree of error detected in the decoding process to the patrol reading unit 33 or the control unit 30. The degree of error, for example, is reported as the number of error bits or the number of times of performing an error correction.

The number of error bits, for example, is the number of error bits within data of a certain unit. The number of times of performing an error correction is the number of times of the error correction process performed until the error correction is successful. The ECC unit 34 includes at least a first level ECC unit and a second level ECC unit that are two ECC processing units having mutually-different correction capabilities. The second level FCC unit has an error correction capability higher than that of the first level ECC unit. For example, the error correction capability is changed by changing the data size configuring a code word and/or the coding system. In a case where an error correction is failed by the first level ECC unit, an error correction is performed by the second level ECC unit. In a case where the error correction performed by the first level ECC unit is successful, the ECC unit 34 reports once as the number of times of performing the error correction. On the other hand, in a case where the error correction performed by the second level ECC unit is successful, the ECC unit 34 reports twice as the number of times of performing the error correction.

The patrol reading unit 33 cyclically performs patrol read for active blocks, in which valid data is recorded, included in the NAND 10. The patrol reading process for all the active blocks is performed within a cycle time Ta. The cycle time Ta is counted up by counting the time at which the memory system 100 is turned on. During a period in which the cycle time Ta elapses, a patrol reading process corresponding to one set is performed. In a case where a command such as a read command or a write command is received from the host 1 during the execution of the patrol reading process, command process performed by the control unit 31 has high priority.

The patrol reading unit 33 reads data of each certain small unit and causes the ECC unit 34 to check the read data. In this embodiment, while the certain unit is one page, another unit may be used as the unit for the patrol reading process. The patrol reading unit 33 determines whether or not the error detected by the ECC unit 34 exceeds a predetermined threshold in the patrol reading process performed in units of pages. For example, the patrol reading unit 33 registers a block including a page of which the degree of error reported from the ECC unit 34 exceeds the predetermined threshold as a defective block in the patrol reading process.

The control unit 31 controls the host interface 32, the patrol reading unit 33, and the ECC unit 34. The control unit 31 performs command processes corresponding to various commands received from the host 1. In such command processes, a process of reading data from the NAND 10, a process of writing data into the NAND 10, and the like are included. The control unit 31, as is necessary, registers and updates the management information loaded into the RAM 20.

Hereinafter, the patrol reading process performed by the patrol reading unit 33 will be described in detail. The patrol reading unit 33 sets the cycle time Ta to be changeable. During a period in which the use period of the NAND 10 is relatively short, the NAND 10 can maintain data for a long period, and accordingly, the cycle time Ta is set to be long, whereby the influence on the execution time of the host command is reduced. In addition, when the NAND 10 is continued to be used, the data retention period of the NAND 10 is shortened, and accordingly, the cycle time Ta is set to be short so as to frequently perform the patrol reading process, whereby a loss of data is prevented.

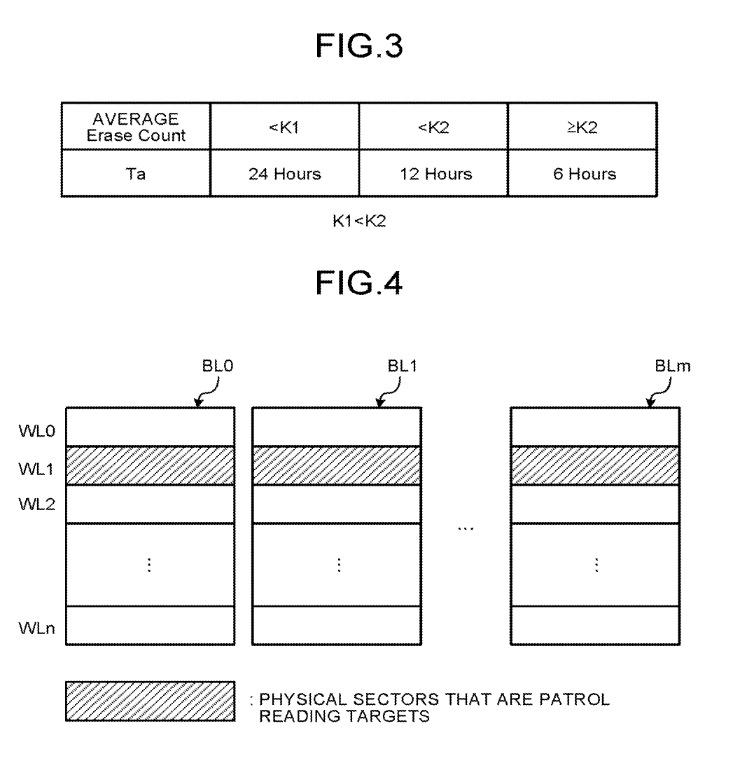

The patrol reading unit 33, for example, uses the average number of times of erasing of blocks used for user data instead of the time. The patrol reading unit 33 changes the cycle time Ta based on the average number of times of erasing of the blocks used for user data. FIG. 3 illustrates a relation between an average number of times of erasing (hereinafter, referred to as an average erase count) of blocks and the cycle time Ta. In the case illustrated in FIG. 3, it is set such that Ta=24 hours in a case where the average erase count is less than K1, Ta=12 hours in a case where the average erase count is K1 or more and K2 or less, and Ta=6 hours in a case where the average erase count is K2 or more. Here, the number of thresholds and the values of Ta illustrated in FIG. 3 are merely an example, and other arbitrary values may be used.

In addition, for example, the cycle time Ta may be set to be changeable according to the following Equation (1). Here, “̂2” represents the square of two. In addition, E1 is a predicted value of the average erase count until the memory system 100 arrives at the end of the life after the use of the memory system 100 is started.

Ta=24*(1−(average erase count/E1)̂2)[Hours] (1)

(Modified Example for Setting Cycle Time to be Changeable)

In a first modified example, the cycle time Ta is determined based on the average number of times of writing per page. In the first modified example, in a case where the average number of times of writing is larger than a threshold, the cycle time Ta is set to be short. In the second modified example, the cycle time Ta is determined based on an average error rate that is a ratio of the number of bit errors to the amount of read data. In the second modified example, in a case where the average error rate is larger than the threshold, the cycle time Ta is set to be short.

FIG. 4 conceptually illustrates the patrol reading process performed by the patrol reading unit 33. FIG. 4 illustrates a plurality of physical blocks BL0, BL1, . . . , BLm included in all the active blocks that are patrol reading targets in the NAND 10. In this embodiment, the patrol reading unit 33, within one cycle time Ta, performs the patrol reading process only for a physical sector MS (see FIG. 2) each including a plurality of memory cells connected to one word line within each of the physical blocks BL0, BL1, . . . , BLm. Accordingly, the number of times of reading and the amount of read data are decreased to be smaller than those of a case where the patrol reading process is performed for a plurality of physical sectors MS each including a plurality of memory cells connected to one of all the word lines within each block.

In the case illustrated in FIG. 4, only physical sectors MS connected to a word line WL1 within a plurality of the physical blocks BL0, BL1, . . . , BLm included in all the active blocks are set as targets for the patrol reading process. In the case illustrated in FIG. 4, when the patrol reading process is started, a physical sector, which belongs to the word line WL1, of the physical block BL0 is read, next, a physical sector, which belongs to the word line WL1, of the physical block BL1 is read, . . . and, next, a physical sector, which belongs to the word line WL1, of the physical block BLm is read. In case of the MLC, within one physical block, a lower page and an upper page connected to the word line WL1 are targets for the patrol reading process. In case of the TLC, within one physical block, a lower page, a middle page, and an upper page connected to the word line WL1 are targets for the patrol reading process.

Since the NAND 10 is frequently damaged in units of blocks, when the patrol reading process for one word line WL per block is performed, the amount of reading can be decreased without lowering data error detection accuracy. In a case where another word line WL is configured to be selected when one cycle time Ta is started, by repeating the cycle time Ta, all the word lines WL can be tested. In other words, when one cycle time Ta is completed, the word line that is the execution target of the patrol reading process may be changed.

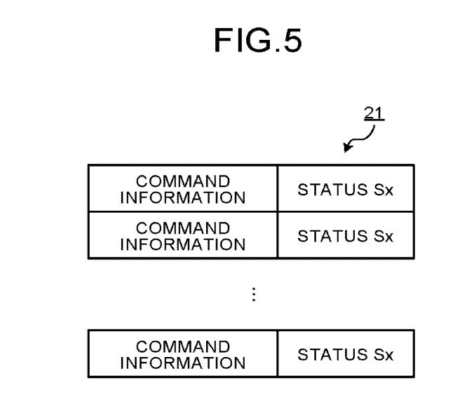

FIG. 5 is a diagram that illustrates the internal structure of the command queue 21 illustrated in FIG. 1. The host can almost simultaneously issue two or more commands to the memory system 100. In other words, for example, after issuing a first read command, the host i may issue a second read/write command before receiving read data from the memory system 100 for the first read command. In addition, for example, after issuing a first write command, the host may issue a second read/write command before starting to transmit write data corresponding to the first write command. For this reason, in order to discriminate a plurality of commands issued from the host 1 from each other, the command queue 21 includes a plurality of entries and can register the plurality of commands. In addition, a status Sx is associated with each entry registered in the command queue 21. Here, “x” represented in a lower-case letter is a number that uniquely designates one of the plurality of entries included in the command queue. In this embodiment, for example, since the queue has 32 entries, numbers 1 to 32 are actual values for the lower-case letter “x”. Such a number is included in a command transmitted by the host and is used as a value discriminating the command from the other commands. As above, the lower-case letter x is a number that designates a command. In the case illustrated in FIG. 5, each entry of the command queue 21 includes a field for a received command and a field in which the status Sx is registered. In addition, the technique for associating a corresponding status with a command and a method of maintaining the status are not limited to those illustrated in FIG. 5, but any other method may be used.

The status Sx represents the execution status of a received command within the memory system 100 and may take one state among Empty, Wait, Read, Pool, Send, and Non Read. Empty represents a state in which the command has not been issued, or all the processes relating to the command have been completed. Wait represents a state in which an access to the NAND 10 is not performed after a read command is issued. In addition, Read represents a state in which data specified by a read command is read from the NAND 10, and the data is written into the transmission buffer 22. Pool represents a state in which reading of data specified by a read command from the NAND 10 to the transmission buffer 22 has been completed, but the host interface 32 has not transmitted the data to the communication line 2. Send represents a state in which, after data corresponding to a read command is completed to be read from the NAND 10, the host interface 32 transmits the data stored in the transmission buffer 22 to the host 1. When the data stored in the transmission buffer 22 is completed to be transmitted by the host interface 32 to the host 1, the status becomes Empty from Send. In addition, Non Read collectively represents a plurality of states in which a command excluding the read command, for example, a write command is received from the host 1, and the process is performed.

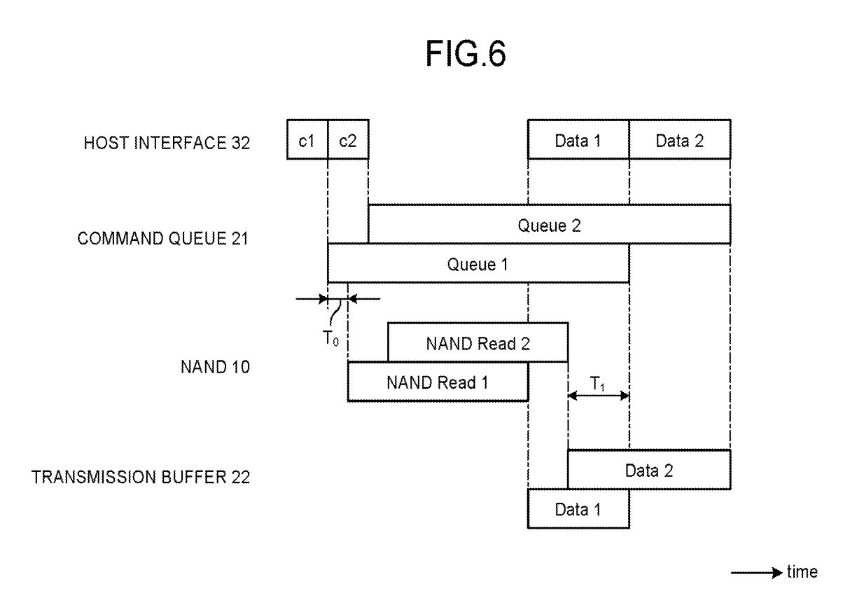

FIG. 6 is a timing chart that illustrates the operating state of each component in the memory system 100 when a read command is received from the host 1. The host 1 transmits a first command c1 to the memory system 100 through the communication line 2. A transmission period of the first command c1 is represented by a square enclosing “c1”. The control unit 31 registers the received first command c1 in the command queue 21 as Queue 1. A rectangle enclosing “Queue 1” represents a period in which Queue 1 is present in the command queue 21. The command Queue 1 registered in the command queue 21 is processed by the control unit 31. In other words, the command Queue 1 registered in the command queue 21, after a slight processing time T0 for the process performed by the control unit 31, is converted by the control unit 31 into a read command for the NAND 10. In addition, a memory access NAND Read 1 is executed by the NAND 10. A rectangle enclosing NAND Read 1 illustrates a period until the NAND 10 completes to transfer data corresponding to a command Queue 1 from the NAND 10 to the transmission buffer 22 after receiving a read command corresponding to the command Queue 1. When the transfer of the data from the NAND 10 to the transmission buffer 22 is completed, the data read from the NAND 10 is temporarily stored in the transmission buffer 22 as transmission data Data1. In the operating state of the transmission buffer 22, a rectangle enclosing the transmission data Data1 represents a period in which the data Data1 is stored in the transmission buffer 22. The transmission data Data1 is transmitted to the host 1 at a speed corresponding to the capability of the communication line 2. In the operating state of the host interface 32, a rectangle enclosing the transmission data Data1 represents a period in which the host interface 32 transmits the data Data1 to the communication line 2. When all the data requested from the host 1 using the command c1 is transmitted to the host 1, the queue entry Queue1 is deleted from the command queue 21, and the data Data1 is deleted from the transmission buffer 22. This queue entry Queue1 is used when a when a separate command is received.

(On-the-Fly Process)

This memory system 100 can process a read command on-the-fly. In the on-the-fly process, data that is simultaneously stored in the transmission buffer 22 is not all the data that is a reading target but, for example, data corresponding to several pages. The data read from the NAND 10 is started to be transmitted to the host 1 through the communication line 2 when the communication line 2 is in an idle state, and a data amount of a minimal unit (for example, 8 kByte) that is necessary for transmission is secured in the transmission buffer 22. Thereafter, the NAND 10 reads data corresponding to the read command Queue1 and continuously transmits the data to the transmission buffer 22, and the transmission buffer continuously transmits the data newly read from the NAND 10 to the host 1. In a case where the on-the-fly process is performed, a rectangle enclosing “Data1” of the transmission buffer 22 is a period from when the transmission of all the read data corresponding to the command c1 from the NAND 10 to the transmission buffer is completed to when the host interface 32 completes transferring all the data stored in the transmission buffer 22 to the host 1.

Also in a case where the host 1 transmits second command c2 to the memory system 100 through the communication line 2, the memory system 100 similarly operates. However, when data Data2 read front the NAND 10 is stored in the transmission buffer 22, in a case where the transmission of the transmission data Data1 corresponding to the first command c1 has not been completed, the host interface 32 cannot simultaneously transmit the data Data1 and Data2. For this reason, as illustrated in FIG. 6, the data Data2 stands by for a delay time T1 until the transmission of the data Data1 is completed.

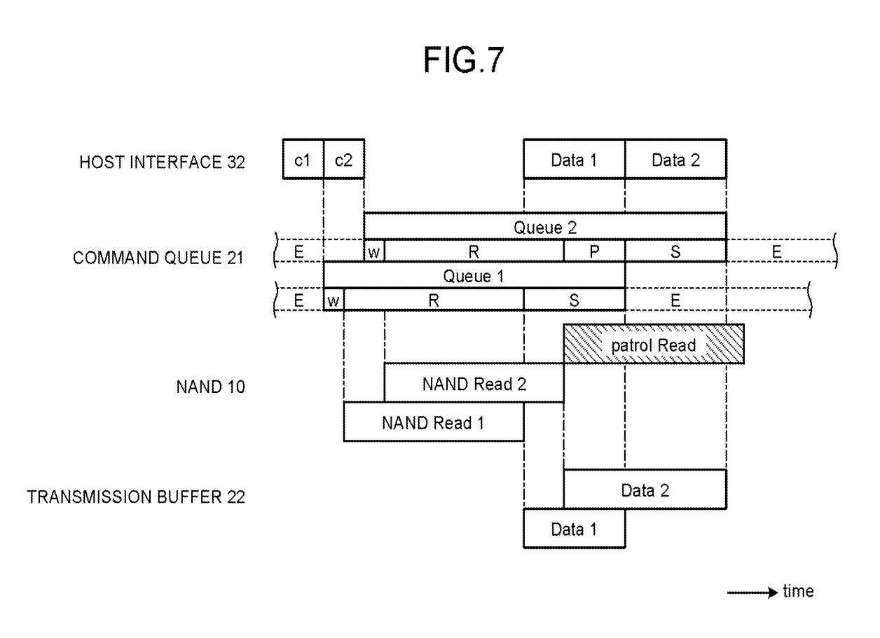

FIG. 7 is a timing chart that illustrates timing for executing the patrol reading process in the reading process illustrated in FIG. 6. A series of operations until the first read command c1 and the second read command are received from the host 1, and the corresponding data Data1 and Data2 is transmitted to the host 1 are the same as those illustrated in FIG. 6. In the case illustrated in FIG. 7, a status added to the command queue 21. In FIG. 7, W corresponds to Sx=Wait, R corresponds to Sx=Read, P corresponds to Sx=Pool, and S corresponds to Sx=Send. Here, E enclosed by broken lines outside the rectangle of the command queue 21 corresponds to Sx=Empty.

As illustrated in FIG. 7, in the first embodiment, the control unit. 31 performs the patrol reading process at timing at which data requested by all the received read commands is completed to be read from the NAND 10. A time during which the patrol reading process is performed and a time during which the host interface 32 is used for the transmission of read data overlap each other, and, during that period, the host 1 cannot transmit a new command. Thus, in this embodiment, the patrol reading process is started during a period in which read data is transmitted to the host 1 from when data requested by all the received read commands is completed to be read from the NAND 10. Accordingly, the influence of the patrol reading process on the response of the command received from the host 1 can be reduced.

In addition, as illustrated in FIG. 7, in a case where the transmission of final read data is completed by the host interface 32 before the patrol reading process performed in units of a minimal unit ends, the host 1 can transmit a next command. The control unit 31 can register this new command in the command queue but cannot access the NAND 10 based on this new command. In this case, the execution of the new command stands by until the patrol reading process ends.

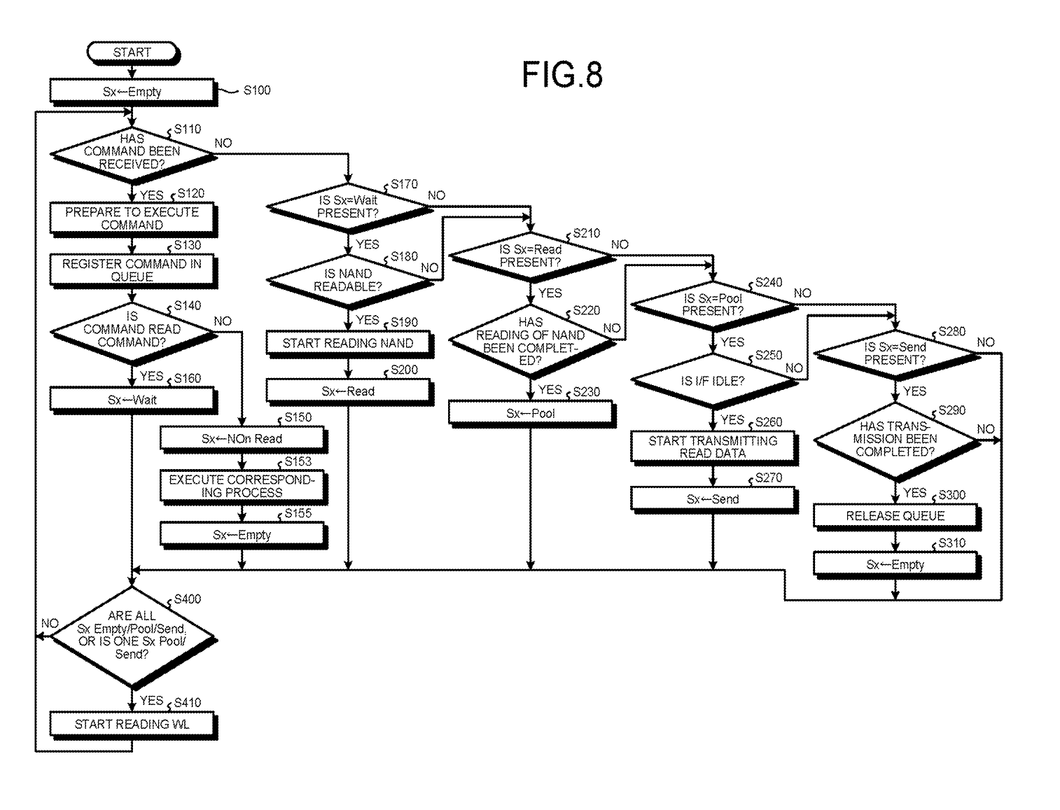

FIG. 8 is a flowchart that illustrates the processing sequence of the control unit 31. When the memory system 100 is started to operate, the control unit 31 initially sets statuses Sx of all the queues of the command queue 21 to “Empty” (Step S100). When a command is received from the host 1 (Yes in Step S110), the control unit 31 analyzes the received command and prepares the execution of the command including a search for the management information and the like (Step S120). In a case where the command is a read command, the preparation for the execution includes searching the logical/physical translation table and specifying the physical address of the NAND 10 corresponding to a logical address specified by the read command. The control unit 31 registers the received co and in the command queue 21 (Step S130). In a case where the received command is a command other than the read command (No in Step S140), the control unit 31 sets Sx=Non Read in the command queue 21 (Step S150). In a case where the command queue 21 is set such that Sx=Non Read, the control unit 31 performs processes corresponding to the command (Step S153). In a stage in which all the processes relating to the command is completed, the control unit 31 releases a queue corresponding to the command in the command queue 21 and sets the status Sx of the queue corresponding to the command to “Empty” (Step S155).

In a case where the received command is a read command (Yes in Step S140), the control unit 31 sets Sx=Wait in the command queue 21 (Step S160).

On the other hand, in a case where any command has not been received from the host 1 (No in Step S110), the control unit 31 determines whether or not there is a queue of Sx=Wait inside the command queue 21 (Step S170). In a case where there is a queue of Sx=Wait inside the command queue 21, the control unit 31 determines whether or not the NAND 10 is readable (Step S180). In a case where the NAND 10 is readable (Yes in Step S180), a reading operation requested by the command supplied from the NAND 10 is started to operate. In accordance with the start of the execution of the reading operation, the status Sx of the command is set to “Read” (Step S200). On the other hand, in a case where an operation of reading NAND 10 cannot be performed in Step S180, the process proceeds to Step S210.

In a case where a queue of Sx=Wait is not present inside the command queue 21 (No in Step S170), the control unit 31 determines whether or not there is a queue of Sx=Read inside the command queue 21 (Step S210). In a case where the queue of Sx=Read is present inside the command queue 21, the control unit 31 determines whether or not an operation of reading data from the NAND 10 into the transmission buffer 22 has been completed (Step S220). In a case where this reading operation has been completed, the control unit 31 sets the status Sx of the command to “Pool” (Step S230). On the other hand, in a case where the reading operation for reading data from the NAND 10 has not been completed (Step S220), the process proceeds to Step S240.

In a case where the queue of Read is not present inside the command queue 21 (No in Step S210), the control unit 31 determines whether or not a queue of Sx=Pool is present inside the command queue 21 (Step S240). In a case where the queue of Sx=Pool is present inside the command queue 21, the control unit 31 determines whether or not the host I/F 32 in the idle state (Step S250). In a case where the host I/F 32 is determined to be in the idle state, the control unit 31 starts a transmission process for transmitting the read data to the host 1 (Step S260). In accordance with the start of the transmission process, the control unit 31 sets the status Sx of the command to “Send” (Step S270). In Step S250, when the host I/F 32 is not in the idle state, the process proceeds to Step S280.

In a case where the queue of Sx=Pool is not present inside the command queue 21 (No in Step S240), the control unit 31 determines whether or not a queue of Sx=Send is present inside the command queue 21 (Step S280). In a case where the queue of Sx=Send is present inside the command queue 21, the control unit 31 determines whether or not the transmission of the read data has been completed (Step S290). In a case where it is determined that the transmission of the read data has been completed, the control unit 31 release the queue of the command (Step S300) and sets the status Sx of the command to “Empty” (Step S310).

In a case where the process of Step S160, S200, S230, S270, or S310 are competed or in a case where a result of the determination is “No” in Step S280 or Step S290, the process proceeds to Step S400. In Step S400, the control unit 31 determines the status Sx of each queue of the command queue 21 and, when the following conditions of (a) and (b) are satisfied, causes the patrol reading unit 33 to perform the patrol reading process (Step S410). (a) All Statuses Sx are either Empty or Pool or Send (b) At least One Status Sx is Pool or Send

Here, the condition (a) represents hat a command (including a read command and a write command) that is currently in a process of executing access to the NAND 10 or a command (Sx=Wait) having a standby state is not present. In addition, the condition (b) represents a time when the host interface 32 transmits read data specified by a read command (Sx=Send) or a time when buffering of the read data into the transmission buffer 22 is completed, and the host interface 32 waits for the transmission of the read data (Sx=Pool).

Accordingly, when the first, condition in which a command currently in a process of executing access to the NAND 10 is not present, and the host interface 32 transmits the read data specified by the read command is satisfied and in a case where the second condition in which a command that is currently in a process of executing access to the NAND 10 is not present, and the buffering of the read data into the transmission buffer 22 is completed is satisfied, the patrol reading unit 33 executes the patrol reading process. On the other hand, in a case where a command (Sx=Wait) that is in the standby state is present, the patrol reading process is not performed.

In Step S410, the patrol reading unit 33 performs the above-described patrol reading process. In this patrol reading process, a physical sector connected to one word line WL per block is set as the target for the patrol reading process.

In the description presented above, while the patrol reading process is configured to be performed when Sx=Send or Sx=Pool, the patrol reading process may be configured to be performed when Sx=Send. In addition, depending on a storage device, there are cases where states that can be taken by the status of each command are different from those described in this embodiment. In such cases, the conditions of Step S400 may be appropriately changed according to the purposes of the conditions (a) and (b) described above.

As above, according to the first embodiment, when a command in a process of executing access to the NAND 10 is not present, and the host interface transmits the data specified by the read command, the patrol reading process is performed. For this reason, the influence of the patrol reading process on the response performance of the command received from the host 1 can be reduced.

In addition, according to the first embodiment, the cycle time of the patrol reading process is shortened based on the average erase count of the NAND 10, and thus, even when the NAND 10 is worn, a loss of data stored in the NAND 10 can be prevented in advance.

Furthermore, when there is a possibility that the patrol reading process of one set cannot be completed during the period of the cycle time Ta, the control unit 31 may ignore the condition (b) in Step S400. In other words, the patrol process may be configured to be performed when each of the statuses Sx of all the command queues is one of Empty/Pool/Send.

### Second Embodiment

In the first embodiment, while the cycle time Ta is configured to be changed according to the average erase count, in a second embodiment, the cycle time Ta is changed according to an increase in the number of bad blocks. As described above, had blocks are unusable blocks that do not normally operate due to various factors, and the number of the bad blocks tends to increase as the use period of the NAND 10 increases.

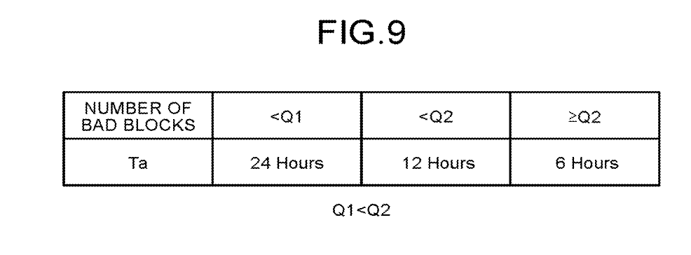

FIG. 9 illustrates the relation between the number of had blocks and the cycle time Ta. In this case, in a case where the number of had blocks is less than Q1, at is set that Ta=24 hours, in a case where the number of had blocks is Q1 or more and less than Q2, it is set that Ta=12 hours, and, in a case where the number of bad blocks is Q2 or more, it is set that Ta=6 hours. For example, Q1 is 50% of the allowable number of bad blocks, and Q2 is 80% of the allowable number of bad blocks. Here, the allowable number of had blocks is the number of the upper limit of the number of had blocks for which the user capacity of the NAND 10 can be secured. Here, the number of the thresholds and the value of Ta illustrated in FIG. 9 represent merely an example, and any other arbitrary value may be used.

As above, according to the second embodiment, the cycle time of the patrol reading process is shortened based on the number of bad blocks of the NAND 10, and thus, even when the NAND 10 is worn, a loss of data stored in the NAND 10 can be prevented in advance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a first memory which is a nonvolatile memory;
a second memory which is a volatile memory;
a host interface connectable to a host; and
a controller configured to:
read first data from the first memory, the first data being data specified by a first co and received from the host through the host interface, the first command being a read command;
buffer the read first data into the second memory;
transmit the buffered first data to the host through the host interface; and
perform a patrol read, when a second command having a state of being in a process of executing access to the first memory is not present and the host interface transmits the buffered first data, the second command being a command received from the host and including the read command, the patrol read including reading the second data and testing the read second data, the second data being data of a certain unit, the second data being stored in the first memory.

2. The memory system according to claim 1, wherein the controller is configured to perform the patrol read when the second command having a state of being in a process of executing access to the first memory is not present and buffering of the first data into the second memory is completed.

3. The memory system according to claim 1, wherein the controller is configured not to perform the patrol read in a case where the second command having a standby state of the access to the first memory is present.

4. The memory system according to claim 2, wherein the controller is configured riot to perform the patrol read in a case where the second command having a standby state of the access to the first memory is present.

5. The memory system according to claim 1, wherein the controller is configured to perform the patrol read when all the received second commands are in a first state, a fourth state, or a fifth state among first to sixth states and at least one of the received second commands is in the fourth state or the fifth state, the first state corresponding to a state in which a process relating to the second command is completed, the second state corresponding to a state in which an access to the first memory is not performed after the first command is received, the third state corresponding to a state in which the first data is transferred from the first memory to the second memory after the first command is received, the fourth state corresponding to a state in which the host interface does not transmit the first data transferred to the second memory to the host, the fifth state corresponding to a state in which the host interface transmits the first data to the host, the sixth state corresponding to a state in which a process excluding the read command is executed.

6. The memory system according to claim 1,
wherein the first memory includes a plurality of blocks, and
wherein the controller is configured to cyclically perform the patrol read, the patrol read including reading data of a first page as the second data and testing the read second data within a cycle time, the first page corresponding to one word line among word lines in a first block among the blocks.

7. The memory system according to claim 6, wherein the controller is configured to perform the patrol read of a second page within the cycle time after the patrol read of a first page, the second page corresponding to a word line among word lines in a second block among the blocks.

8. The memory system according to claim 6,
wherein the first memory includes a plurality of blocks, and
wherein the controller is configured to change the cycle time based on the average number times of erasing data of the blocks.

9. The memory system according to claim 6,
wherein the first memory includes a plurality of blocks, and
wherein the controller is configured to change the cycle time based on the number of bad blocks.

10. The memory system according to claim 1, wherein the testing performed in the patrol read includes an error correction using an error correction code.

11. A method of controlling a memory system including a first memory which is a nonvolatile memory, a second memory which is a volatile memory, and a host interface, the method comprising:
receiving a first command from a host;
reading first data from the first memory, the first data being data specified by the first command, the first command being a read command;
buffering the read first data into the second memory;
transmitting the buffered first data to the host; and
performing a patrol read, when a second command having a state of being in a process of executing access to the first memory is riot present and the host interface transmits the buffered first data, the second command being a command received from the host and including the read command, the patrol read including reading the second data and testing the read second data, the second data being data of a certain unit, the second data being stored in the first memory.

12. The method according to claim 11, the method further comprising performing the patrol read when the second command having a state of being in a process of executing access to the first memory is not present and buffering of the first data into the second memory is completed.

13. The method according to claim 11, the method further comprising not performing the patrol read in a case where the second command having a standby state of the access to the first memory is present.

14. The method according to claim 12, the method further comprising not performing the patrol read in a case where the second command having a standby state of the access to the first memory is present.

15. The method according to claim 11, the method further comprising performing the patrol read when all the received second commands are in a first state, a fourth state, or a fifth state among first to sixth states and at least one of the received second commands is in the fourth state or the fifth state, the first state corresponding to a state in which a process relating to the second command is completed, the second state corresponding to a state in which an access to the first memory is not performed after the first command is received, the third state corresponding to a state in which the first data is transferred from the first memory to the second memory after the first command is received, the fourth state corresponding to a state in which the host interface does not transmit the first data transferred to the second memory to the host, the fifth state corresponding to a state in which the host interface transmits the first data to the host, the sixth state corresponding to a state in which a process excluding the read command is executed.

16. The method according to claim 11,
wherein the first memory includes a plurality of blocks,
the method further comprising cyclically performing the patrol read, the patrol read including reading data of a first page as the second data and testing the read second data within a cycle time, the first page corresponding to one word line among word lines in a first block among the blocks.

17. The method according to claim 16, the method further comprising performing the patrol read of a second page within the cycle time after the patrol read of a first page, the second page corresponding to a word line among word lines in a second block among the blocks.

The method according to claim 16,
wherein the first memory includes a plurality of blocks,
the method further comprising changing the cycle time based on the average number of times of erasing data of the blocks.

19. The method according to claim 16,
wherein the first memory includes a plurality of blocks,
the method further comprising changing the cycle time based on the number of bad blocks.

20. The method according to claim 11, wherein the testing performed in the patrol ad includes an error correction using an error correction code.
